(19) United States
(12) Patent Application Publication
(10) Pub. No.: US 2012/0289015 A1
(43) Pub. Date: Nov. 15, 2012

(54) METHOD FOR FABRICATING SEMICONDUCTOR DEVICE WITH ENHANCED CHANNEL STRESS

(75) Inventors: Ching-Sen Lu, Tainan City (TW); Wen-Han Hung, Kaohsiung City (TW); Tsai-Fu Chen, Hsinchu City (TW); Tzyy-Ming Cheng, Hsinchu City (TW)

(73) Assignee: UNITED MICROELECTRONICS CORP., HSINCHU (TW)

(21) Appl. No.: 13/106,970

(22) Filed: May 13, 2011

(51) Int. Cl. H01L 21/336

(52) U.S. Cl. 438/299; 257/E21.409

(57) ABSTRACT

A method for fabricating a semiconductor device with enhanced channel stress is provided. The method includes the following steps. Firstly, a substrate is provided. Then, at least one source/drain region and a channel are formed in the substrate. A dummy gate is formed over the channel. A contact structure is formed over the source/drain region. After the contact structure is formed, the dummy gate is removed to form a trench.

### FIELD OF THE INVENTION

The present invention relates to a method for fabricating a semiconductor device, and more particularly to a method for fabricating a semiconductor device with enhanced channel stress.

### BACKGROUND OF THE INVENTION

Because the length of the gate can not be limitlessly reduced any more and new materials have not been proved to be used in the metal-oxide-semiconductor field-effect transistor (MOSFET), adjusting mobility has become an important role to improve the performance of the integrated circuit. The lattice strain of the channel is widely applied to increase mobility during the process of fabricating the MOSFET. For example, the hole mobility of the silicon with the lattice strain can be 4 times as many as the hole mobility of the silicon without the lattice strain, and the electron mobility with the lattice strain can be 1.8 times as many as the electron mobility of the silicon without the lattice strain. Therefore, a tensile stress can be applied to an N-channel of an N-channel MOSFET by changing the structure of the transistor, or a compression stress can be applied to a P-channel of a P-channel MOSFET by changing the structure of the transistor. In a case that the channel is stretched, the electron mobility can be improved. Whereas, in a case that the channel is compressed, the hole mobility is improved.

In the technology for manufacturing an integrated circuit, a gate structure including a high dielectric constant (high-K) insulating layer and a metal gate (hereafter called HK/MG for short) has been widely used. Generally, after a poly-silicon dummy gate is removed, the metal gate of the HK/MG is filled. It is found that the removal of the poly-silicon dummy gate may increase the efficacy of applying tensile stress to the channel. Therefore, the performance of the MOSFET may be enhanced by utilizing these properties in order to obviate the drawbacks encountered from the prior art.

### SUMMARY OF THE INVENTION

In accordance with an aspect, the present invention provides a method for fabricating a semiconductor device with enhanced channel stress is provided. The method includes the following steps. Firstly, a substrate is provided. Then, at least one source/drain region and a channel are formed in the substrate. A dummy gate is formed over the channel. A contact structure is formed over the source/drain region. After the contact structure is formed, the dummy gate is removed to form a trench.

In an embodiment, the substrate is a silicon substrate, and the dummy gate is a poly-silicon dummy gate.

In an embodiment, the step of forming the dummy gate includes sub-steps of: forming an interface layer over the channel, forming a high-K insulating layer over the interface layer, forming a barrier metal layer over the high-K insulating layer, and forming the dummy gate over the barrier metal layer.

In an embodiment, the method further includes steps of: forming a first hard mask over the dummy gate, and forming a second hard mask over the first hard mask.

In an embodiment, the method further includes steps of: forming a first spacer on sidewalls of the dummy gate, and forming a second spacer on sidewalls of the first spacer.

In an embodiment, the method further includes steps of: forming a contact etch stop layer over the dummy gate and the source/drain region, and forming an interlayer dielectric layer over the contact etch stop layer.

In an embodiment, the step of forming the contact structure includes sub-steps of: etching the interlayer dielectric layer and the contact etch stop layer to form a contact hole, filling a barrier layer into the contact hole, and forming a contact conductor on the barrier layer, thereby forming the contact structure.

In an embodiment, if the channel is an N-channel, the barrier layer is made of a tensile material such as titanium, titanium nitride or a combination thereof, and the contact conductor is made of tungsten.

In an embodiment, if the channel is a P-channel, the barrier layer is made of a compressive material such as tantalum, tantalum nitride or a combination thereof, and the contact conductor is made of copper.

In an embodiment, if the channel is an N-channel, a bottom of the contact hole has a concave profile.

In an embodiment, if the channel is a P-channel, a bottom of the contact hole has a convex profile.

In an embodiment, if the channel is an N-channel, the contact hole is as an elongated slot.

In an embodiment, if the channel is a P-channel, the contact hole is composed of plural small openings.

In an embodiment, the step of removing the dummy gate further includes a sub-step of performing a flattening process to remove a part of the interlayer dielectric layer and a part of the contact etch stop layer.

In an embodiment, the method further includes a step of filling a metal structure into the trench.

In an embodiment, the step of filling the metal structure further includes sub-steps of: filling a work function metal layer into the trench, and forming a metal gate on the work function metal layer.

In an embodiment, the metal gate is made of aluminum.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A˜1E illustrate a partial process flow of a HK/MG gate-last process according to an embodiment of the present invention; and

FIG. 2 schematically illustrates the top concave profile of the source/drain region of the N-channel MOSFET and the top convex profile of the source/drain region of the P-channel MOSFET according to the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

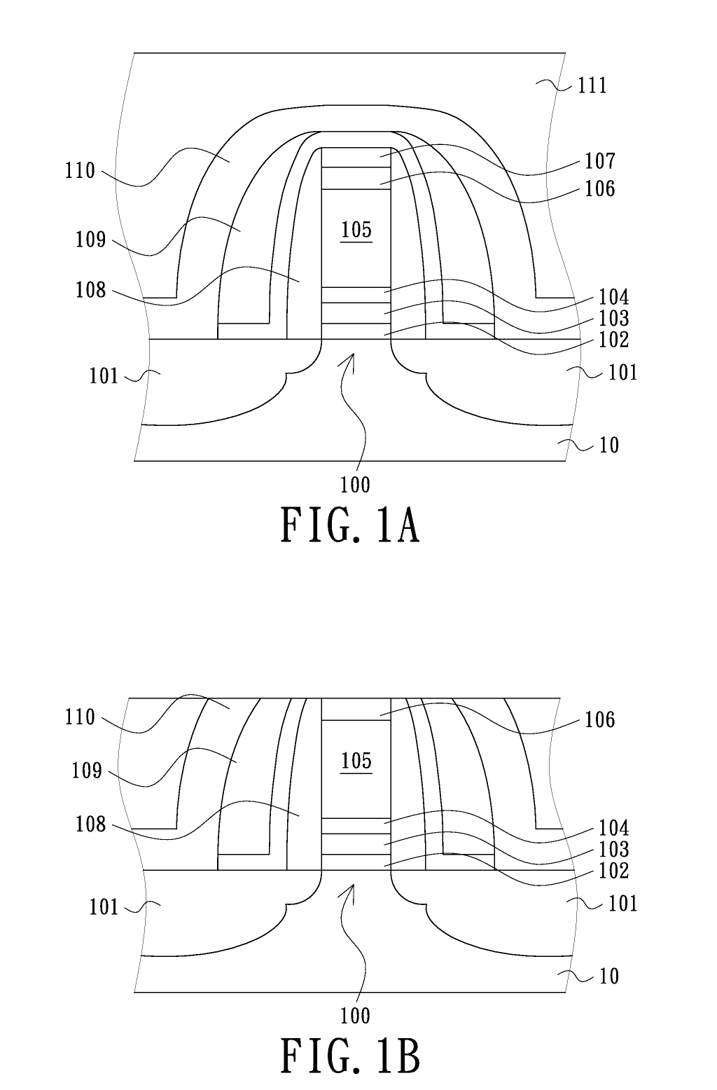

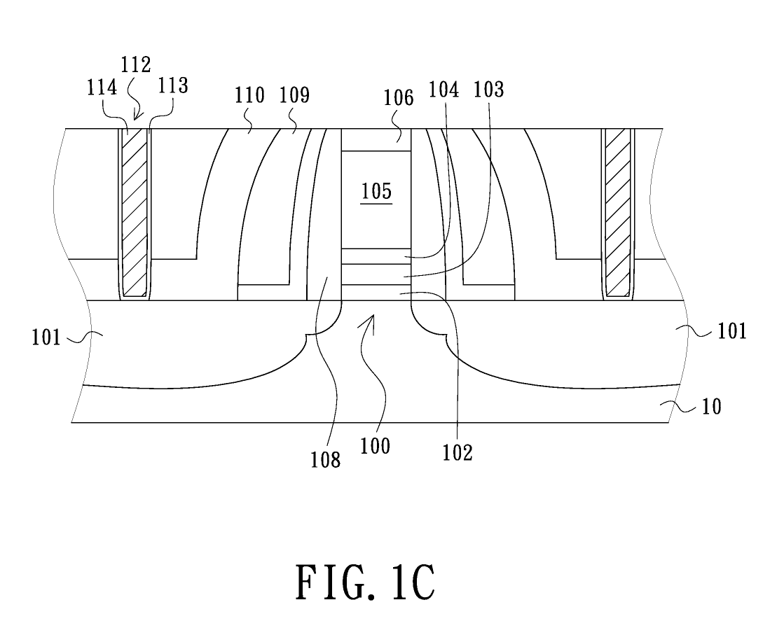

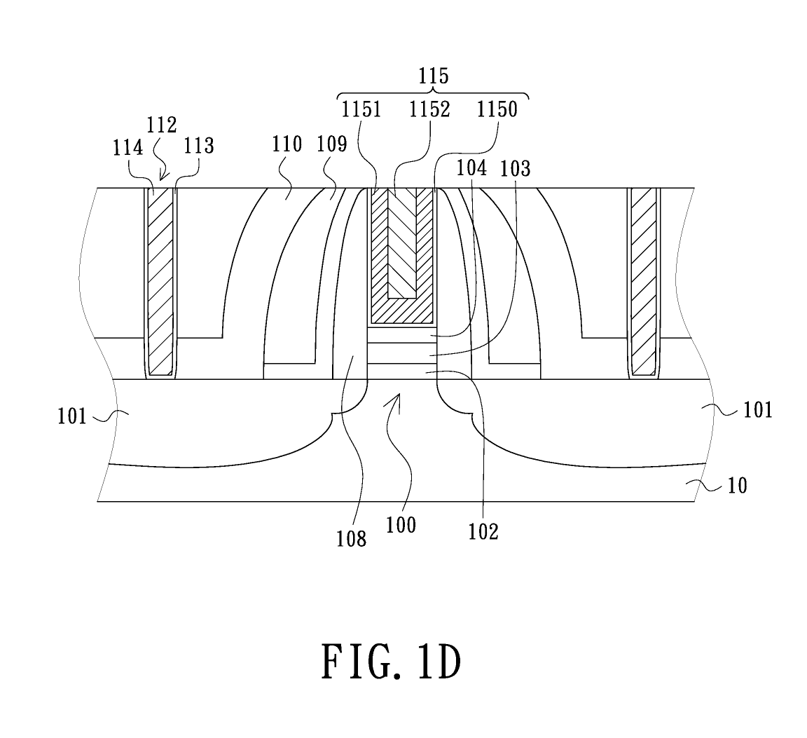

FIGS. 1A-1E illustrate a partial process flow of a HK/MG gate-last process according to an embodiment of the present invention. As shown in FIG. 1A, a channel 100 and a source/drain region 101 are defined in a substrate 10. An interface layer 102, a high-K insulating layer 103, a barrier metal layer 104, a dummy gate 105, a first hard mask 106, a second hard mask 107, a first spacer 108, a second spacer 109, a contact etch stop layer 110 (CESL) and an interlayer dielectric layer (ILD) 111 are formed over the channel 100. The substrate 10 is a silicon substrate. The interface layer 102 is made of silicon dioxide. The high-K insulating layer 103 is made of hafnium dioxide (HfO₂). The barrier metal layer 104 is made of titanium nitride (TiN). The dummy gate 105 is a poly-silicon dummy gate. The first hard mask 106 is made of silicon nitride. The second hard mask 107 is made of silicon dioxide. The first spacer 108 is either a composite layer structure including a silicon dioxide layer and a silicon nitride layer, or a pure silicon dioxide layer. The second spacer 109 is a composite layer structure including a silicon dioxide layer and a silicon nitride layer. The contact etch stop layer 110 is a silicon nitride layer with high tensile stress. The interlayer dielectric layer 111 is made of silicon dioxide.

Then, as shown in FIG. 1B, a flattening process such as a top-cut chemical mechanical polishing (CMP) process is performed to remove partial structures of FIG. 1A to form a flat top surface. For example, a part of the interlayer dielectric layer 111, a part of the contact etch stop layer 110 and the second hard mask 107 (e.g. made of silicon dioxide) are removed. As a result, the first hard mask 106 (e.g. made of silicon nitride) is exposed.

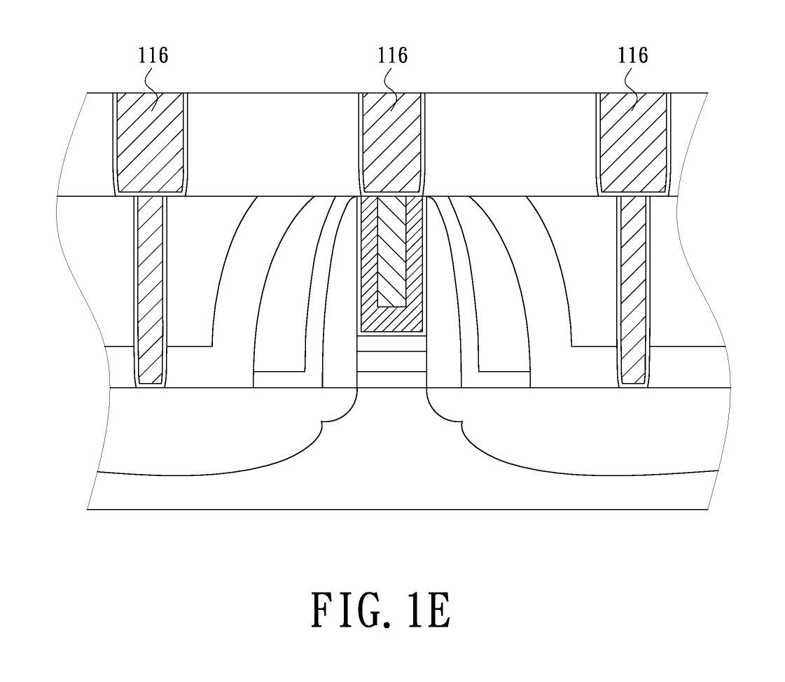

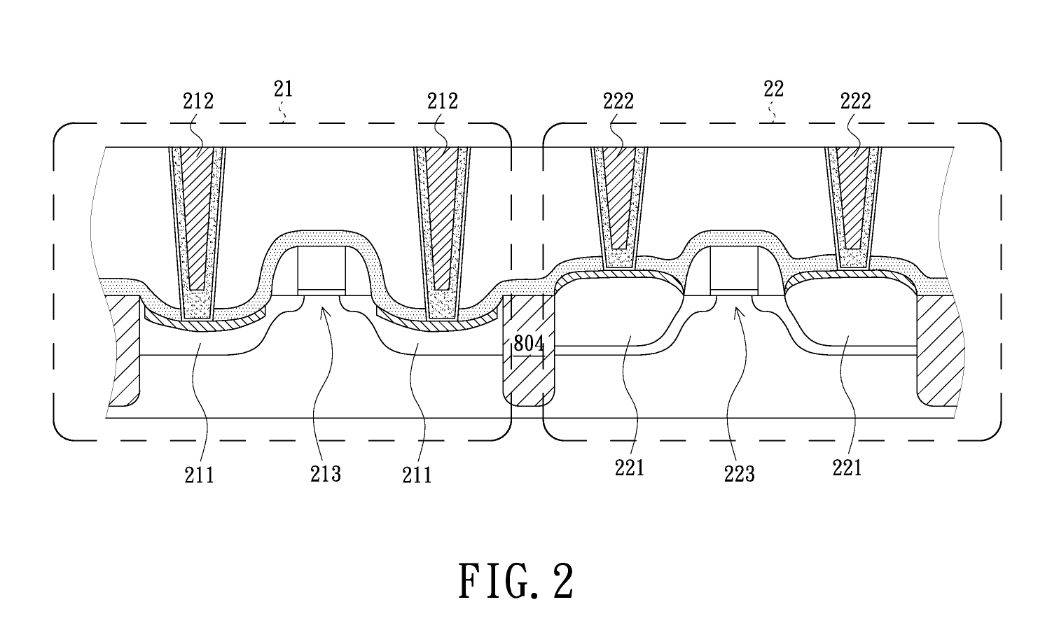

Then, a contact structure is formed over the source/drain region 101. That is, after a contact hole 112 is formed by an etching process, a barrier layer 113 and a contact conductor 114 are sequentially filled into the contact hole 112 to form the resulting structure of FIG. 1C. For utilizing the contact structure to adjust the channel stress, the material and the shape of the contact structure may be properly selected according to the polarity of the channel. For example, in order to increase the tensile stress of the channel of an N-channel MOSFET, the barrier layer 113 may be made of a tensile material such as titanium, titanium nitride or a combination thereof, and the contact conductor 114 may be made of tungsten. Whereas, in order to increase the compression stress of a channel of a P-channel MOSFET, the barrier layer 113 may be made of a compressive material such as tantalum (Ta), tantalum nitride (TaN) or a combination thereof, and the contact conductor 114 may be made of copper. However, if the barrier layers 113 and the contact conductors 114 of different regions (e.g. N-channel region and P-channel region) of the same chip are made of different materials, the fabricating complexity and the fabricating cost will be increased. For reducing the fabricating complexity and the fabricating cost, by simply changing the shapes of the source/drain region and the contact hole, the barrier layers 113 in the contact structures of all regions may be made of the same material, and the contact conductors 114 in the contact structures of all regions may be made of the same material. For example, as shown in FIG. 2, the top of the source/drain region 211 of the N-channel MOSFET 21 may have a concave profile, so that the bottom of the contact hole 212 may go deep into the source/drain region 211 to increase the tensile stress of the channel 213. Whereas, the source/drain region 221 under the bottom of the contact hole 222 of the P-channel MOSFET 22 may have a convex profile to provide compressive stress to the channel. For example, the convex profile of the source/drain region 221 is an epitaxial layer made of silicon germanium (SiGe). Alternatively, the contact hole 212 of the N-channel MOSFET may be designed as an elongated slot, so that the contact area is increased to enhance the tensile stress of the channel. Whereas, the contact hole 222 of the P-channel MOSFET may be designed as plural small openings, so that the tensile stress of the channel is not considerably increased. Moreover, the stress of the channel may be adjusted according to the distance between the contact hole and the gate. For example, the contact hole for providing compressive stress is closer to the gate of the P-channel MOSFET, but the contact hole for providing compressive stress is farther from the gate of the N-channel MOSFET, so that the adverse influence of the compressive stress on the N-channel is reduced. Whereas, the contact hole for providing the tensile stress is closer to the gate of the N-channel MOSFET, but the contact hole for providing the tensile stress is farther from the gate of the P-channel MOSFET, so that the adverse influence of the compressive stress on the P-channel is reduced.

After the barrier layer 113 and the contact conductor 114 are filled into the contact hole 112, as shown in FIG. 1D, the first hard mask 106 is removed to expose the poly-silicon dummy gate 105. The poly-silicon dummy gate 105 is removed to create a trench, and a metal structure 115 is filled into the trench. It is found that the removal of the poly-silicon dummy gate 105 may increase the efficacy of applying tensile stress to the channel. That is, after the channel stress is adjusted by the contact structure, the channel stress (especially the tensile stress applied to the channel) is further strengthened by the removal of the poly-silicon dummy gate 105. Since the channel stress is enhanced without the need of increasing step in the fabricating process, the drawbacks encountered from the prior art will be overcome. Moreover, as shown in FIG. 1D, the metal structure 115 comprises an etch stop layer 1150, a work function metal layer 1151 and a metal gate 1152. The etch stop layer 1150 is made of made of titanium nitride (TiN). For the P-channel MOSFET, the work function metal layer 1151 is made of titanium nitride (TiN). For the N-channel MOSFET, the work function metal layer 1151 is made of titanium aluminum (TiAl). The metal gate 1152 is made of aluminum (Al).

Afterwards, as shown in FIG. 1E, a conductive structure 116 is formed on the metal structure 115 and the contact conductor 114. The subsequent steps are similar to those of the prior art technology, and are not redundantly described herein.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for fabricating a semiconductor device with enhanced channel stress, the method comprising steps of:
providing a substrate;
forming at least one source/drain region and a channel in the substrate;
forming a dummy gate over the channel;
forming a contact structure over the source/drain region; and
removing the dummy gate to form a trench after the contact structure is formed.

2. The method according to claim 1, wherein the substrate is a silicon substrate, and the dummy gate is a poly-silicon dummy gate.

3. The method according to claim 1, wherein the step of forming the dummy gate includes sub-steps of:
forming an interface layer over the channel;
forming a high-K insulating layer over the interface layer;
forming a barrier metal layer over the high-K insulating layer; and
forming the dummy gate over the barrier metal layer.

4. The method according to claim 1, further comprising steps of:
forming a first hard mask over the dummy gate; and
forming a second hard mask over the first hard mask.

5. The method according to claim 1, further comprising steps of:
forming a first spacer on sidewalls of the dummy gate; and
forming a second spacer on sidewalls of the first spacer.

6. The method according to claim 1, further comprising steps of:
forming a contact etch stop layer over the dummy gate and the source/drain region; and
forming an interlayer dielectric layer over the contact etch stop layer.

7. The method according to claim 6, wherein the step of forming the contact structure includes sub-steps of:
etching the interlayer dielectric layer and the contact etch stop layer to form a contact hole;
filling a barrier layer into the contact hole; and
forming a contact conductor on the barrier layer, thereby forming the contact structure.

8. The method according to claim 7, wherein if the channel is an N-channel, the barrier layer is made of a tensile material.

9. The method according to claim 8, wherein the tensile material is titanium, titanium nitride or a combination thereof, and the contact conductor is made of tungsten.

10. The method according to claim 6, wherein if the channel is a P-channel, the barrier layer is made of a compressive material.

11. The method according to claim 10, wherein the compressive material is tantalum, tantalum nitride or a combination thereof, and the contact conductor is made of copper.

12. The method according to claim 6, wherein if the channel is an N-channel, a bottom of the contact hole has a concave profile.

13. The method according to claim 6, wherein if the channel is a P-channel, a bottom of the contact hole has a convex profile.

14. The method according to claim 6, wherein if the channel is an N-channel, the contact hole is as an elongated slot.

15. The method according to claim 6, wherein if the channel is a P-channel, the contact hole is composed of plural small openings.

16. The method according to claim 6, wherein the step of removing the dummy gate further includes a sub-step of performing a flattening process to remove a part of the interlayer dielectric layer and a part of the contact etch stop layer.

17. The method according to claim 1, further comprising a step of filling a metal structure into the trench.

18. The method according to claim 17, wherein the step of filling the metal structure further includes sub-steps of:
filling a work function metal layer into the trench; and
forming a metal gate on the work function metal layer.

19. The method according to claim 18, wherein the metal gate is made of aluminum.
